(19) United States
(12) Patent Application Publication
(10) Pub. No.: US 2026/0090381 A1
(43) Pub. Date: Mar. 26, 2026

(54) HETEROJUNCTION BIPOLAR TRANSISTOR

(71) Applicant: GlobalFoundries U.S. Inc., Malta, NY (US)

(72) Inventors: Steven M. Shank, Jericho, VT (US); Alexander Montgomery Derrickson, Saratoga Springs, NY (US); Sarah Ann McTaggart, Essex Junction, VT (US); Megan Elizabeth Lydon-Nuhfer, Essex Junction, VT (US); John J. Pekarik, Underhill, VT (US)

(21) Appl. No.: 18/894,886

(22) Filed: Sep. 24, 2024

(51) Int. Cl. H01L 23/373; H01L 21/48; H01L 29/66; H01L 29/737

(52) U.S. Cl. CPC H10W 40/254; H10D 10/021; H10D 10/821; H10W 99/00

(57) ABSTRACT

The present disclosure relates to semiconductor structures and, more particularly, to heterojunction bipolar transistors and methods of manufacture. The structure includes: a semiconductor substrate; a collector region over the semiconductor substrate; an intrinsic base over the collector region; an electrically insulating heat dissipative material at a junction of the collector region and the intrinsic base; an extrinsic base over the intrinsic base; and an emitter region adjacent to the extrinsic base.

### BACKGROUND

The present disclosure relates to semiconductor structures and, more particularly, to heterojunction bipolar transistors and methods of manufacture.

A heterojunction bipolar transistor (HBT) is a type of bipolar junction transistor (BJT) that uses different semiconductor materials for the emitter and base regions, creating a heterojunction. The HBT can handle signals of very high frequencies, up to several hundred GHz. The HBT can be used, for example, in radio frequency (RF) systems, and in applications requiring a high power efficiency, such as RF power amplifiers in cellular phones and in automotive RADAR applications requiring higher frequency (˜140 GHz) operations.

### SUMMARY

In an aspect of the disclosure, a structure comprises: a semiconductor substrate; a collector region over the semiconductor substrate; an intrinsic base over the collector region; an electrically insulating heat dissipative material at a junction of the collector region and the intrinsic base; an extrinsic base over the intrinsic base; and an emitter region adjacent to the extrinsic base.

In an aspect of the disclosure, a structure comprises: a semiconductor substrate; a subcollector region on the semiconductor substrate; a collector region over the subcollector region, the collector region comprising a semiconductor material that is different than the sub-collector region; an intrinsic base over the collector region; an undercut region within an area between the subcollector region, the collector region and the intrinsic base; electrically insulating heat dissipative material in the undercut region; an extrinsic base over the intrinsic base; and an emitter region adjacent to the extrinsic base.

In an aspect of the disclosure, a method comprises: forming a collector region over a semiconductor substrate; forming an intrinsic base over the collector region; forming an electrically insulating heat dissipative material at a junction of the collector region and the intrinsic base; forming an extrinsic base over the intrinsic base; and forming an emitter region adjacent to the extrinsic base.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a structure and respective fabrication processes in accordance with aspects of the present disclosure.

FIGS. 2-6 show additional structures in accordance with aspects of the present disclosure.

FIGS. 7A-7E show respective fabrication processes for fabricating the structure shown in FIG. 1 in accordance with aspects of the present disclosure.

### DETAILED DESCRIPTION

The present disclosure relates to semiconductor structures and, more particularly, to heterojunction bipolar transistors and methods of manufacture. More specifically, the present disclosure relates to heterojunction bipolar transistors (HBT) integrated with an electrically insulating heat dissipative material, e.g., diamond or other carbon-based insulator material. Advantageously, the structures described herein improve self-heating and high frequency performance (e.g., fT and Fmax) of the HBT, in addition to being able to absorb (e.g., mitigate) heat and/or replace an external heat sink. The HBTs described herein also exhibit lower parasitic capacitance.

In more specific embodiments, the electrically insulating heat dissipative material, e.g., diamond or other carbon-based insulator material, may be in contact with or adjacent to an extrinsic base, intrinsic base, collector region and/or subcollector region of an HBT. In embodiments, the intrinsic base material and subcollector material may be, for example, SiGe material; whereas the emitter region and collector region may comprise Si material, as non-limiting examples. In further embodiments, via structures comprising the electrically insulating heat dissipative material may be in contact with the electrically insulating heat dissipative material which is adjacent to the HBT layers. The electrically insulating heat dissipative material may also include a cavity structure under the extrinsic base region, amongst other variations described herein. In any of the embodiments, the electrically insulating heat dissipative material may dissipate heat that is generated at the collector-base junction (which would otherwise dissipate into the underlying semiconductor substrate). Implementations of the HBTs described herein may be used in, for example, automotive RADAR applications which require higher temperature and higher frequency (˜140 GHz) operation.

The structures of the present disclosure can be manufactured in a number of ways using a number of different tools. In general, though, the methodologies and tools are used to form structures with dimensions in the micrometer and nanometer scale. The methodologies, i.e., technologies, employed to manufacture the structures of the present disclosure have been adopted from integrated circuit (IC) technology. For example, the structures are built on wafers and are realized in films of material patterned by photolithographic processes on the top of a wafer. In particular, the fabrication of the structures uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

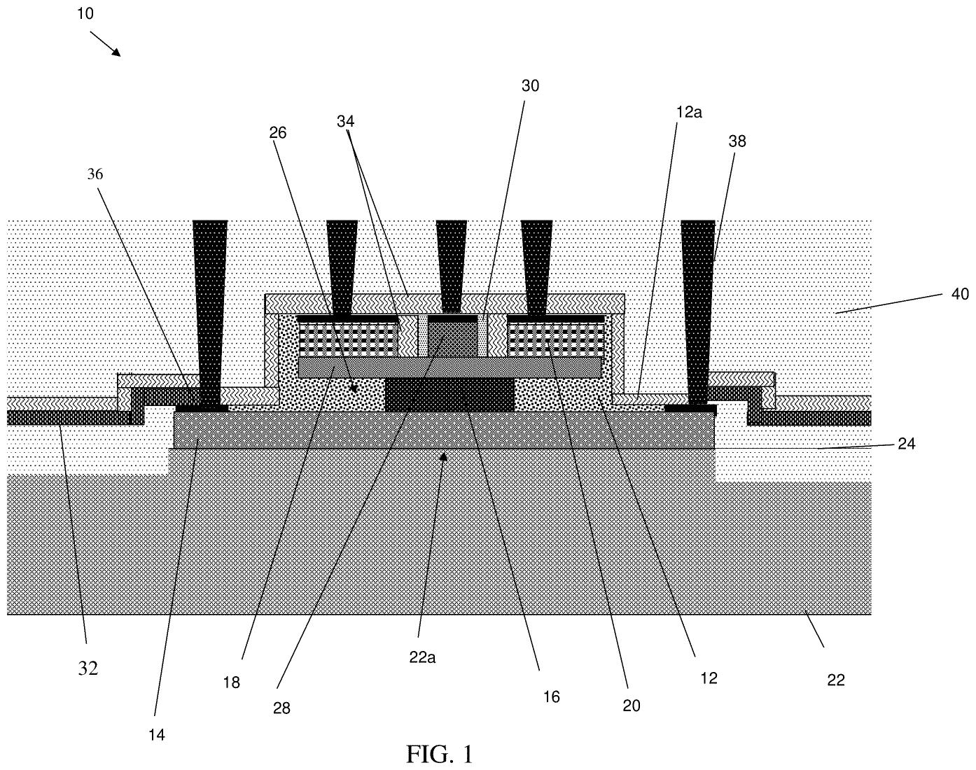

FIG. 1 shows a structure in accordance with aspects of the present disclosure. In embodiments, the structure 10 of FIG. 1 comprises an HBT which includes an electrically insulating heat dissipative material 12 that contacts a subcollector region 14, a collector region 16, an intrinsic base 18, and an extrinsic base 20. In embodiments, the electrically insulating heat dissipative material 12 may preferably be diamond material; although other materials are contemplated herein. For example, the insulating heat dissipative material 12 may be carbon-based materials, or other insulator and heat dissipating material with a dielectric constant of about 5.5 or greater and a thermal conductivity greater than oxide, for example, of about 2200 W/m-K or greater. The electrically insulating heat dissipative material 12 may be used as a heatsink to absorb (e.g., mitigate) heat that is generated at a junction between the collector region 16 and the intrinsic base region 18. This heat dissipation, in turn, will increase device performance.

In more specific embodiments, the structure 10 includes a semiconductor substrate 22. The semiconductor substrate 22 may be semiconductor on insulator (SOI) technologies or a bulk substrate as known in the art. In embodiments, the semiconductor substrate 22 may be any semiconductor material, e.g., Si, SiGe, SiGeC, SiC, GaAs, InAs, InP, and other III/V or II/VI compound semiconductors with a suitable single crystallographic orientation (e.g., a (100), (110), (111), or (001) crystallographic orientation). In further embodiments, the semiconductor substrate 22 may be p-doped semiconductor material for an NPN device or n-doped for a PNP device. The insulator material in the SOI technologies may comprise any suitable material, including silicon oxide, sapphire, other suitable insulating materials, and/or combinations thereof. An exemplary insulator layer may be a buried oxide layer (BOX).

FIG. 1 further shows the subcollector region 14 on the semiconductor substrate 22 and, more particularly, on a raised pedestal 22a of the semiconductor substrate 22. The pedestal 22a may be surrounded by insulator material 24, e.g., oxide based materials. In embodiments, the subcollector region 14 may be epitaxial grown semiconductor material. For example, in embodiments, the subcollector region 14 may be SiGe material which is epitaxially grown on the semiconductor substrate 22. The epitaxial process may also include, for example, an in-situ doping process. For example, the subcollector region 14 may be n-doped semiconductor material for an NPN device or p-doped for a PNP device. The n-type dopant may be, e.g., Arsenic (As), Phosphorus (P) and Antimony (Sb); whereas the p-type material may be, e.g., boron.

The collector region 16 may be provided on the subcollector region 14. The collector region 16 may comprise semiconductor material that can be selectively etched with respect to the sub-collector region 14 and the intrinsic base 18. For example, in embodiments, the collector region 16 may be Si material that is epitaxially grown on the subcollector region 14. The Si material may be intrinsic Si material. The collector region 16 may have a smaller profile, e.g., width, than the subcollector region 14.

An intrinsic base 18 may be provided over the collector region 16. The intrinsic base 18 may be epitaxially grown over the collector region 16 and the electrically insulating heat dissipative material 12. The intrinsic base 18 may be SiGe material epitaxially grown with an in-situ doping. For example, the intrinsic base 18 may include p-type dopant (e.g., boron) for an NPN device or an n-type dopant (e.g., arsenic) for a PNP device. In embodiments, the intrinsic base 18 may have a larger profile, e.g., width, than the collector region 16.

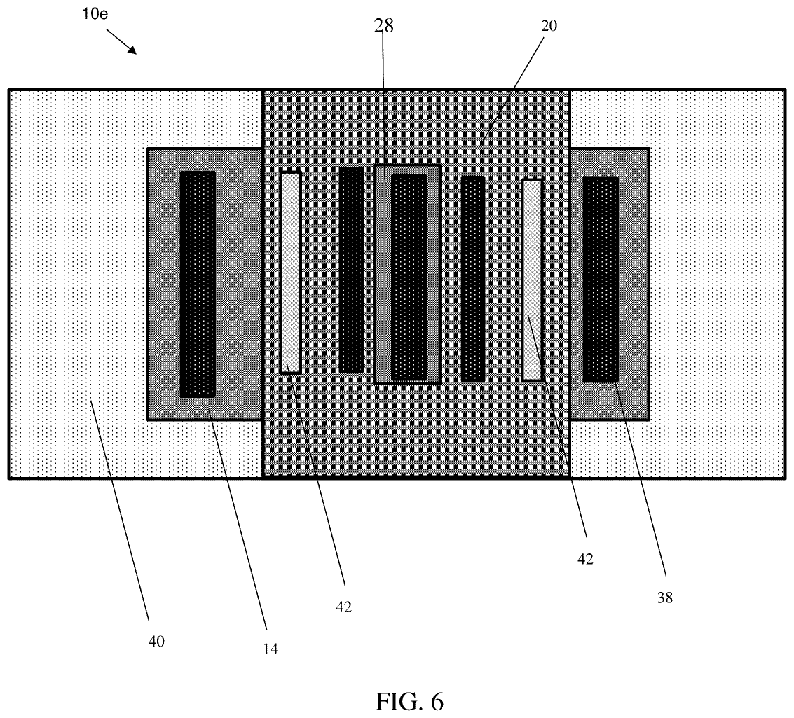

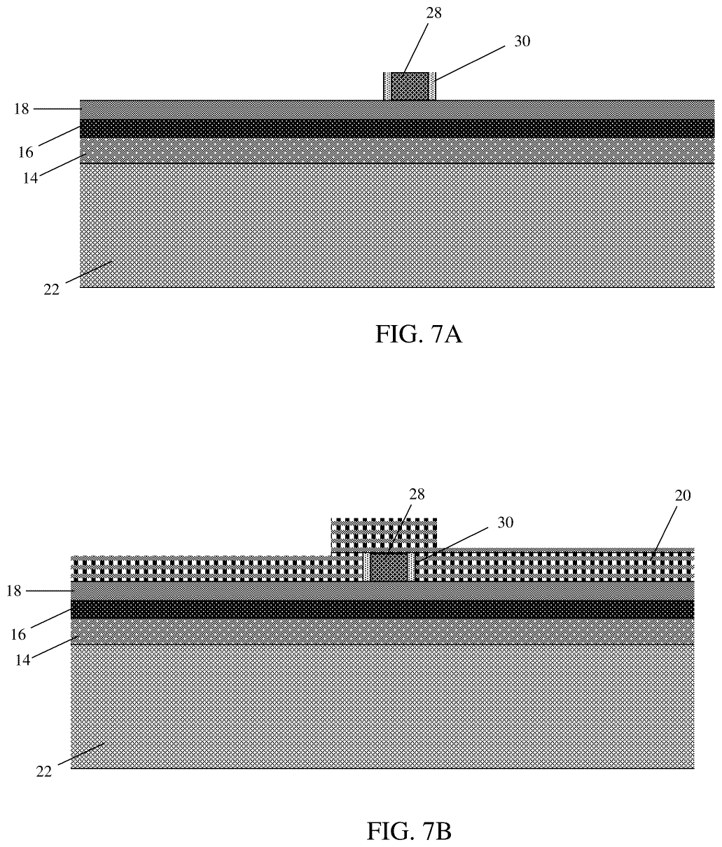

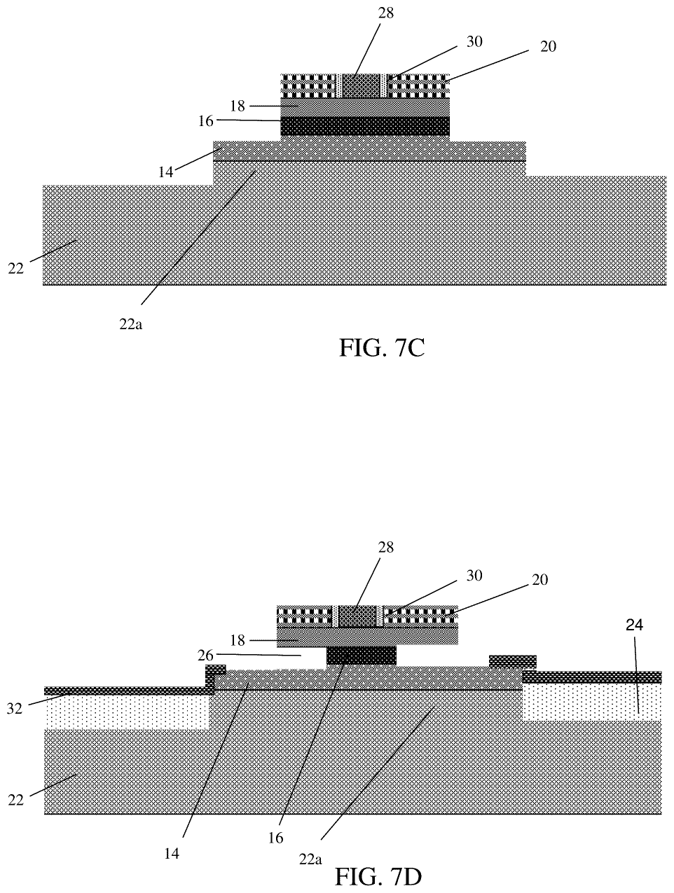

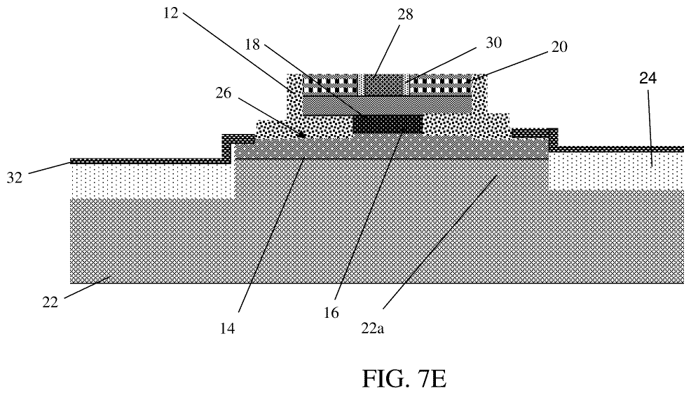

As should be understood by those of skill in the art, the different profiles, e.g., dimensions, of the intrinsic base 18, collector region 16 and the subcollector region 14 forms an undercut region 26. This undercut region 26 may be formed by the processes described with respect to FIGS. 7A-7D. The undercut region 26 may accommodate the electrically insulating heat dissipative material 12. For example, in the undercut 26, the electrically insulating heat dissipative material 12 contacts the underside of the intrinsic base 18, a sidewall of the collector region 16 and a top surface of the subcollector region 14. The electrically insulating heat dissipative material 12 may also extend outwards forming a tabbed portion 12a, extending beyond the sidewall of the extrinsic base 20.

FIG. 1 further shows the extrinsic base 20 and the emitter region 28. The extrinsic base 20 and the emitter region 28 may be formed over the intrinsic base 18 using epitaxial growth processes as described herein. In embodiments, the extrinsic base 20 may be Si or SiGe as examples. The extrinsic base 20 may be epitaxially grown on the intrinsic base 18 with an in-situ dopant. For example, the extrinsic base 20 may include a p-type dopant (e.g., boron) for an NPN device or an n-type dopant (e.g., arsenic) for a PNP device. The electrically insulating heat dissipative material 12, e.g., diamond, may extend onto the sidewalls of the extrinsic base 20 and the intrinsic base 18, in addition to within the undercut 26. In further embodiments, the electrically insulating heat dissipative material 12 surrounds the extrinsic base 20 and the intrinsic base 18.

The extrinsic base 20 may be separated and electrically isolated from the emitter region 28 by insulator materials 30, 34. In embodiments, the insulator material 30 may be sidewall spacers on the sidewalls of the extrinsic base 20. The insulator material 30 may be an oxide or nitride material and the insulator material 32 may be a barrier nitride material, for example. In embodiments, the insulator material 34 may line the extrinsic base 20, the top of the emitter region 28, and the electrically insulating heat dissipative material 12. In further embodiments, the insulator material 34 may be optionally formed between the extrinsic base 20 and the emitter region 28, depending on the patterning of the material of the extrinsic base 20. An oxide or nitride material 32 may be provided under the insulator material 34.

Silicide contacts 36 may be formed on the active regions of the device, e.g., the emitter region 28, the extrinsic base 20 and the subcollector region 14. As should be understood by those of skill in the art, the silicide process begins with deposition of a thin transition metal layer, e.g., nickel, cobalt or titanium, over fully formed and patterned semiconductor devices. After deposition of the material, the structure is heated allowing the transition metal to react with exposed silicon (or other semiconductor material as described herein) in the active regions of the semiconductor device, forming a low-resistance transition metal silicide. Following the reaction, any remaining transition metal is removed by chemical etching, leaving silicide contacts 36 in the active regions of the device.

FIG. 1 further shows contacts 38 formed to the silicide contacts 36 on the emitter region 28, the extrinsic base 20 and the subcollector region 14. In this way, the contacts 18 electrically connect to the collector region 16, the extrinsic base 18 and the emitter region 28. The contacts 38 may be formed within trenches formed in interlevel dielectric material 40. The interlevel dielectric material 40 may be layers of oxide and nitride, deposited by conventional deposition methods, e.g., chemical vapor deposition (CVD) process. The contacts 38, e.g., wiring structures or interconnect structures, can be formed by conventional lithography, etching and deposition methods known to those of skill in the art.

By way of example of conventional lithography, etching and deposition methods, a resist is formed over the interlevel dielectric material 40 which is exposed to energy (light) and developed utilizing a conventional resist developer to form a pattern (opening). An etching process with a selective chemistry, e.g., reactive ion etching (RIE), will be used to transfer the pattern from the patterned photoresist layer to form one or more trenches in the interlevel dielectric material 40. Following the resist removal by a conventional oxygen ashing process or other known stripants, conductive material, e.g., aluminum, copper, tungsten, etc., can be deposited by any conventional deposition processes, e.g., CVD processes. Any residual material on the surface of the interlevel dielectric material 40 can be removed by conventional chemical mechanical polishing (CMP) processes.

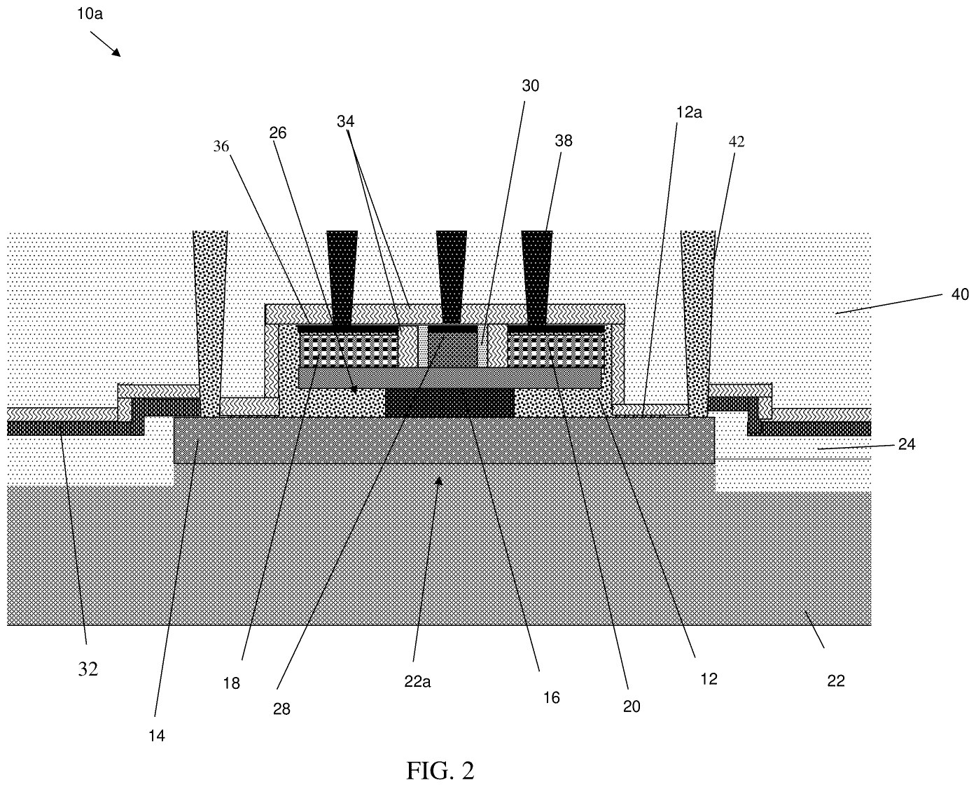

FIG. 2 shows a structure in accordance with additional aspects of the present disclosure. In the structure 10a of FIG. 2, a via structure 42 comprising the electrically insulating heat dissipative material extends to the subcollector region 14. As in the previous embodiment, the electrically insulating heat dissipative material may be diamond, carbon-based material as examples. The remaining features of the structure 10a are similar to the structure 10 of FIG. 1 such that no further explanation is required for a complete understanding of the present disclosure.

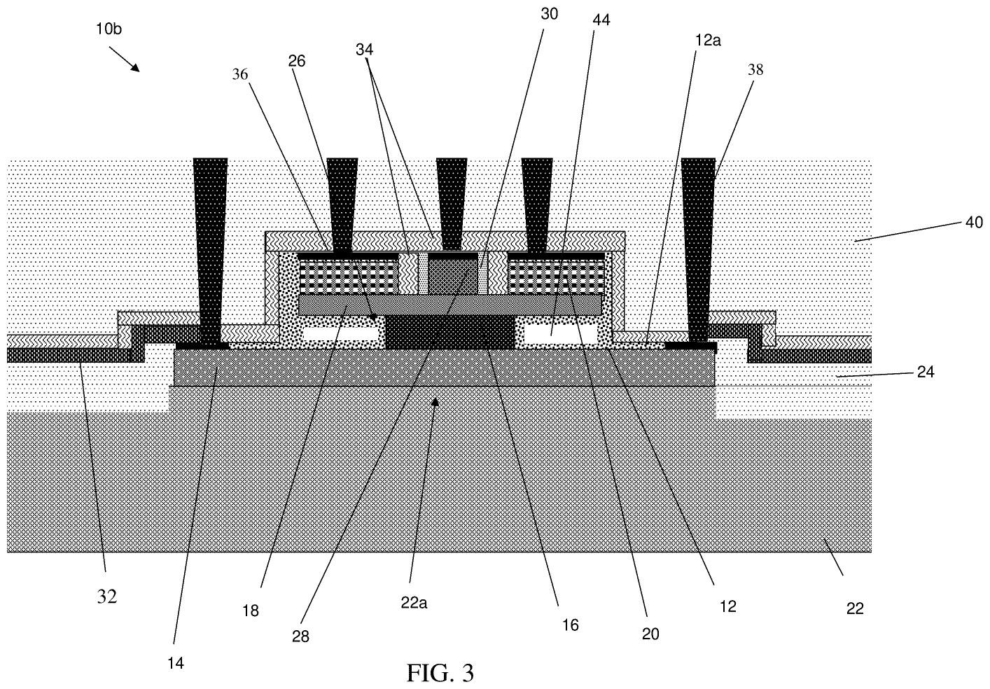

FIG. 3 shows another structure in accordance with additional aspects of the present disclosure. In the structure 10b of FIG. 3, an airgap 44 may be provided within the electrically insulating heat dissipative material 12. In this embodiment, the airgap 44 may be provided between the intrinsic base 18, the subcollector region 14 and a side of the collector region 16. In further embodiments, the electrically insulating heat dissipative material 12 may line the bottom and side surfaces of the extrinsic base 20, the upper surface of the subcollector region 14 and the sides of the collector region 16. The remaining features of the structure 10a are similar to the structure 10 of FIG. 1 such that no further explanation is required for a complete understanding of the present disclosure.

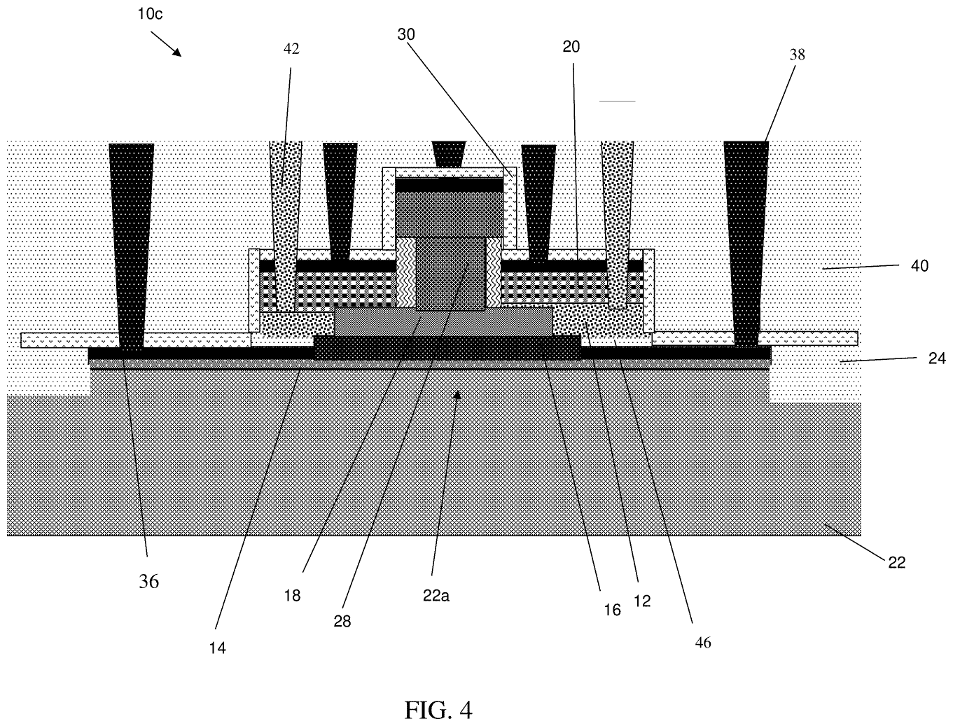

FIG. 4 shows another structure in accordance with aspects of the present disclosure. In the structure 10c of FIG. 4, the emitter region 28 is T-shaped. In addition, the subcollector region 14 has a larger profile, e.g., dimension, compared to the collector region 16 and the intrinsic base 18 and, similarly, the collector region 16 has a larger profile, e.g., dimension, compared to the intrinsic base 18. In this way, the electrically insulating heat dissipative material 12 may still be in an undercut region, e.g., adjacent to the smaller profile collector region 16. Also, in this embodiment, the electrically insulating heat dissipative material 12 may be separated from the subcollector region 14 by insulator material 46, e.g., oxide material. Moreover, the electrically insulating heat dissipative material 12 extends to or beyond an edge of the extrinsic base 20.

Still referring to FIG. 4, the via structure 42 comprising the electrically insulating heat dissipative material extends to and contacts the electrically insulating heat dissipative material 12. In embodiments, the via connect structure 42 may extend through or on a side of the extrinsic base 20. The contacts 38 formed on the silicide contacts 36 electrically connected to the emitter region 28, the extrinsic base 20 and the subcollector region 14. In this configuration, the contacts 38 and the via structure 42 may be provided in parallel and in an alternating configuration as shown in FIG. 6. The remaining features of the structure 10c are similar to the structure 10a of FIG. 1 such that no further explanation is required for a complete understanding of the present disclosure.

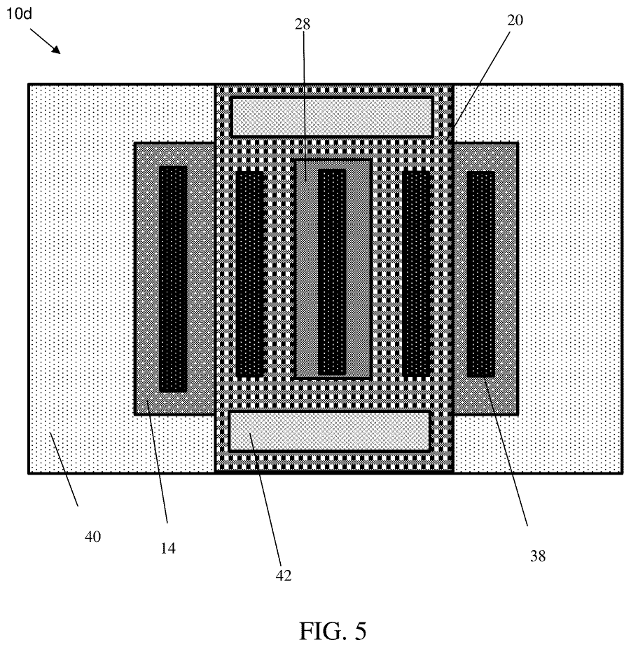

FIG. 5 shows a top view of a structure in accordance with aspects of the present disclosure. In this structure 10d, the via structures 42 are perpendicular to the contacts 38. The via structures 42 may extend through the extrinsic base 20 and contact to the underlying electrically insulating heat dissipative material 12. It should be understood by those of skill in the art that as in any of the embodiments, the electrically insulating heat dissipative material 12 within the undercut region may include an airgap as described with respect to FIG. 3. The remaining features of the structure 10d are similar to the structure 10c of FIG. 4 such that no further explanation is required for a complete understanding of the present disclosure.

FIG. 6 shows a top view of a structure in accordance with aspects of the present disclosure. In this structure 10e, the via structures 42 are parallel and alternating with respect to the contacts 38. The via structures 42 may extend through the extrinsic base 20 and contact to the underlying electrically insulating heat dissipative material 12. The remaining features of the structure 10e are similar to the structure 10c of FIG. 4 such that no further explanation is required for a complete understanding of the present disclosure.

FIGS. 7A-7E show respective fabrication processes for fabricating the structure shown in FIG. 1. It should be understood that similar processes may be used to form the structures shown in FIGS. 2-6.

In FIG. 7A, the semiconductor materials of the subcollector region 14, the collector region 16, the intrinsic base 18 and the emitter region 28 are epitaxially grown on the semiconductor substrate 22. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The epitaxial growth may be performed at a temperature of from 300° C. to 800° C. The epitaxial growth can be performed utilizing any well-known precursor gas or gas mixture. Carrier gases like hydrogen, nitrogen, helium and argon can be used. A dopant (n-type or p-type, as defined below) is typically added to the precursor gas or gas mixture as noted with respect to FIG. 1. An annealing process may be performed to drive in the respective dopants into the respective semiconductor materials.

Still referring to FIG. 7A, the emitter region 20 may be pattern using conventional lithography and patterning processes, e.g., RIE. The sidewall spacers 30 may be formed on the sidewalls of the emitter region 20. In embodiments, the sidewall spacers 30 may be oxide or nitride formed by a conventional deposition process such as CVD. Following the deposition process, the sidewall spacer material is subjected to an anisotropic etching process which results in the formation of the sidewall spacers 30. As should be understood by those of skill in the art, the anisotropic etching process includes a lateral etching component that etches the sidewall spacer material on horizontal surfaces. In embodiments, the etchant can comprise an etchant chemistry of, for example, diluted solution of hydrofluoric acid (HF).

In in FIG. 7B, the material for the extrinsic base region 20 may be epitaxially grown over the patterned emitter region 28 and the intrinsic base 18. In FIG. 7C, the subcollector region 14, the collector region 16, the intrinsic base 18, and the extrinsic base 20 may be patterned using conventional lithography and etching processes. In embodiments, the etching process may slightly recess into the semiconductor substrate 22, resulting in the raised pedestal 22a. In embodiments, the subcollector region 14 may have the same dimensions as the raised pedestal 22a.

In FIG. 7D, a nitride barrier material 32 may be provided over the structure and patterned to expose the underlying semiconductor materials 14, 16, 18, 20. The nitride barrier material 32 may deposited by a conventional CVD process followed by a conventional lithography and etching process to at least expose the collector region 16. The semiconductor material of the collector region 16 may undergo a selective etching process to form the undercut 26. By way of example, the undercut 26 may be formed by a wet etching process comprising NH₄OH, which is selective to the material of the collector region 16.

In FIG. 7E, the electrically insulating heat dissipative material 12 may be blanket deposited over the exposed semiconductor materials 14, 16, 28, 20, 22 and, in particularly, within the undercut region 26. The electrically insulating heat dissipative material 12 may be deposited by a conventional CVD process. In the least, the electrically insulating heat dissipative material 12 will be in contact with the junction of the collector region 16 and the intrinsic base region 18.

In embodiments, the deposition process of the electrically insulating heat dissipative material 12 may result in the structure 10 of FIG. 1, or due to a pinch-off phenomena the structure 10b of FIG. 3 with the airgap. Alternatively, the airgap may be formed by lining the exposed surfaces of the semiconductor materials 14, 16, 28, 20, 22 with the electrically insulating heat dissipative material 12, followed by a resist formation in the undercut region over the semiconductor materials 14, 16, 28, 20, 22, an etching process of the semiconductor materials 14, 16, 28, 20, 22 and subsequent deposition of the insulator material. In either scenario, the electrically insulating heat dissipative material 12 may be subjected to a patterning process to form the structure 10 of FIG. 1, for example, wherein the electrically insulating heat dissipative material 12 contacts and dissipates heat away from the collector-base junction. The processes continue to FIG. 1 to form the remaining structures, e.g., contacts 38, etc.

The HBTs can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a semiconductor substrate;
a collector region over the semiconductor substrate;
an intrinsic base over the collector region;
an electrically insulating heat dissipative material at a junction of the collector region and the intrinsic base;
an extrinsic base over the intrinsic base; and
an emitter region adjacent to the extrinsic base.

2. The structure of claim 1, wherein the electrically insulating heat dissipative material is a heatsink comprising one of diamond and carbon-based material.

3. The structure of claim 1, wherein the electrically insulating heat dissipative material comprises a material with a thermal conductivity greater than oxide.

4. The structure of claim 1, further comprising an undercut region adjacent to the collector region, wherein the electrically insulating heat dissipative material is within the undercut region and under the intrinsic base.

5. The structure of claim 4, wherein the electrically insulating heat dissipative material contacts a sidewall of the extrinsic base.

6. The structure of claim 4, further comprising an airgap within the electrically insulating heat dissipative material.

7. The structure of claim 4, wherein the collector region comprises material that is different than material of the intrinsic base.

8. The structure of claim 4, further comprising a sub-collector region which is under the collector region, wherein the collector region, the intrinsic base region and the subcollector region comprise different dimensions.

9. The structure of claim 4, further comprising contacts electrically connecting to the collector region, the extrinsic base and the emitter region.

10. The structure of claim 9, further comprising via structures comprising the electrically insulating heat dissipative material and which contact the electrically insulating heat dissipative material which is at the junction of the collector region and the intrinsic base.

11. The structure of claim 10, wherein the via structures are parallel to and alternate with the contacts.

12. The structure of claim 10, wherein the via structures are perpendicular to the contacts.

13. A structure comprising:
a semiconductor substrate;
a subcollector region on the semiconductor substrate;
a collector region over the subcollector region, the collector region comprising a semiconductor material that is different than the sub-collector region;
an intrinsic base over the collector region;
an undercut region within an area between the subcollector region, the collector region and the intrinsic base;
electrically insulating heat dissipative material in the undercut region;
an extrinsic base over the intrinsic base; and
an emitter region adjacent to the extrinsic base.

14. The structure of claim 13, wherein the electrically insulating heat dissipative material surrounds the extrinsic base and the intrinsic base.

15. The structure of claim 13, wherein the electrically insulating heat dissipative material is at a junction of the collector region and the intrinsic base.

16. The structure of claim 13, wherein the electrically insulating heat dissipative material comprises a thermal conductivity greater than oxide.

17. The structure of claim 13, further comprising an airgap within the electrically insulating heat dissipative material under the extrinsic base.

18. The structure of claim 13, further comprising via structures comprising the electrically insulating heat dissipative material and which contact the electrically insulating heat dissipative material which is at the junction of the collector region and the intrinsic base.

19. The structure of claim 13, wherein the electrically insulating heat dissipative material comprises diamond.

20. A method comprising:
forming a collector region over a semiconductor substrate;
forming an intrinsic base over the collector region;
forming an electrically insulating heat dissipative material at a junction of the collector region and the intrinsic base;
forming an extrinsic base over the intrinsic base; and
forming an emitter region adjacent to the extrinsic base.
